(19) United States
(12) Patent Application Publication
(10) Pub. No.: US 2011/0259413 A1
(43) Pub. Date: Oct. 27, 2011

(54) Hazy Zinc Oxide Film for Shaped CIGS/CIS Solar Cells

(75) Inventors: Robert D. Wieting, Simi Valley, CA (US); Chester A. Farris, III, Yorba Linda, CA (US)

(73) Assignee: Stion Corporation, San Jose, CA (US)

(21) Appl. No.: 13/087,082

(22) Filed: Apr. 14, 2011

Related U.S. Application Data
(60) Provisional application No. 61/326,313, filed on Apr. 21, 2010.

(51) Int. Cl. H01L 31/0224; H01L 31/18

(52) U.S. Cl. 136/256; 438/73; 257/E31.032

(57) ABSTRACT

A method for fabricating a shaped thin film photovoltaic device includes providing a length of tubular glass substrate having an inner diameter, an outer diameter, a circumferential outer surface region covered by an absorber layer and a window buffer layer overlying the absorber layer. The substrate is placed in a vacuum of between about 0.1 Torr to about 0.02 Torr and a mixture of reactant species derived from diethylzinc species, water species, and a carrier gas are introduced, as well as a diborane species. The substrate is heated to form a zinc oxide film with a thickness of 0.75-3 μm, a haziness of at least 5%, and an electrical resistivity of less than about 2.5 milliohm-cm.

### CROSS-REFERENCE TO RELATED APPLICATION

This application claims priority from U.S. Provisional Application No. 61/326,313, titled “Hazy Zinc Oxide Film for Shaped CIGS/CIS Solar Cells,” filed Apr. 21, 2010, with inventors Robert D. Wieting and Chester A. Farris, III, commonly assigned, and hereby incorporated by reference in its entirety herein for all purpose.

### BACKGROUND OF THE INVENTION

This invention relates generally to photovoltaic materials and a method of manufacturing such materials. The invention provides a method and structure for forming a thin film photovoltaic cell with a hazy transparent conductive oxide (TCO) layer based on absorber material comprising a copper indium disulfide species.

In the process of manufacturing CIS and/or CIGS type thin films, there are various manufacturing challenges, for example, maintaining structure integrity of substrate materials, ensuring uniformity and granularity of the thin film material. While conventional techniques in the past have addressed some of these issues, they are often inadequate in various situations. Therefore, it is desirable to have improved systems and method for manufacturing thin film photovoltaic devices.

### BRIEF SUMMARY OF THE INVENTION

A method and a structure for forming a thin film photovoltaic cell is provided, in particular to form hazy zinc oxide thin film over shaped solar cells. The method includes providing a length of tubular glass substrate having an inner diameter, an outer diameter, a circumferential outer surface region covered by an absorber layer and a window buffer layer overlying the absorber layer through the length. The tubular glass substrate has a substantially co-centered cylindrical heating rod inserted within the inner diameter and through the length of the tubular glass substrate. The tubular glass substrate is held in a vacuum environment ranging from 0.1 Torr to about 0.02 Ton. Then a mixture of reactant species derived from diethylzinc species and water species and a carrier gas are introduced. In addition, a diborane species is introduced at a controlled flow rate into the mixture of reactant species. The gases are then heated by the cylindrical heating rod, to result in forming a zinc oxide film overlying the window buffer layer. preferably the zinc oxide film has a thickness from 0.75-3 μm, a haziness of 5% and greater, and an electrical resistivity of about 2.5 milliohm-cm and less.

In an alternative embodiment, a method for forming a thin film photovoltaic device includes providing a shaped substrate member including a surface region and forming a first electrode layer over the surface region. An absorber material comprising a copper species, an indium species, and a selenide species is formed over the first electrode layer, and then a window buffer layer comprising a cadmium selenide species is formed over the absorber material. Finally, a zinc oxide layer of about 0.75 to 3 microns in thickness overlying the window buffer layer is formed using precursor gases including a zinc species and an oxygen species and an inert carrier gas. The shaped substrate member is maintained at a temperature of greater than about 130 degrees Celsius substantially uniformly throughout the surface region during forming the zinc oxide layer and extended annealing of the zinc oxide layer, thereby leading to a hazy surface optical characteristics and a bulk grain size of about 3000 Angstroms to about 5000 Angstroms within the zinc oxide layer.

The invention enables a thin film tandem photovoltaic cell to be fabricated using conventional equipment. It provides a thin film photovoltaic cell that has an improved conversion efficiency compared to a conventional photovoltaic cells, in a cost effective way.tric energy.

### BRIEF DESCRIPTION OF THE DRAWINGS

FIG. 1 is a process flow diagram illustrating a method of fabricating a thin film photovoltaic device on shaped substrate;

FIGS. 2-6 are enlarged sectional views illustrating a method of fabricating thin film photovoltaic devices on shaped substrates; and

FIGS. 6A and 6B are diagrams illustrating loading configurations of shaped substrates for fabricating thin film photovoltaic devices according to embodiments of the present invention.

### DETAILED DESCRIPTION OF THE INVENTION

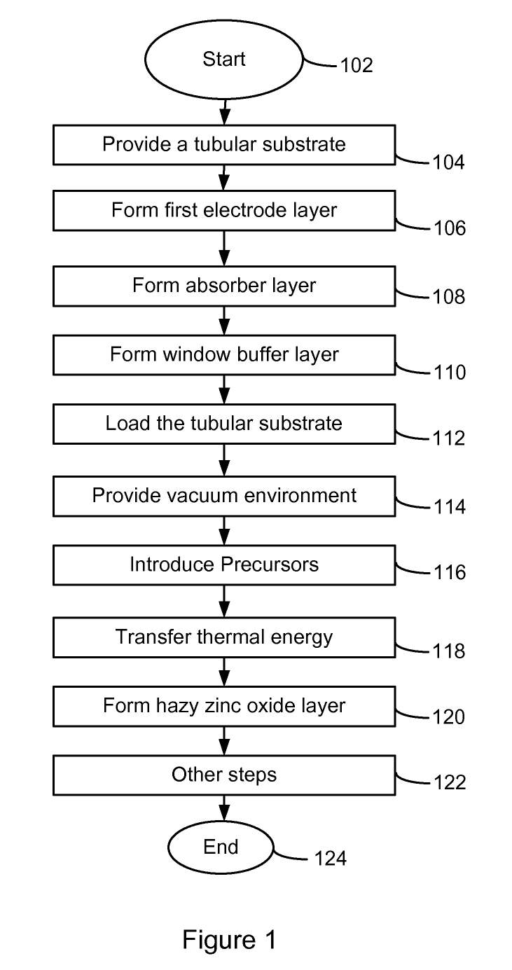

This invention provides a method and structure for forming a thin film photovoltaic cell, particularly a hazy zinc oxide thin film over shaped solar cells. FIG. 1 is a simplified process flow diagram illustrating a method of forming a photovoltaic cell on a tubular glass substrate according to an embodiment of the present invention. As shown, the method begins with a Start step (Step 102). A shaped glass substrate is provided which has a cylindrical tubular shape characterized by a length, an inner diameter and an outer diameter. A circumferential surface region is defined by the length and the outer diameter. The tubular glass substrate is soda lime glass in a specific embodiment, however, other transparent materials including fused silica and quartz may also be used. Other shaped substrates including cylindrical rod, sphere, semi-cylindrical tile, as well as non-planar or even flexible foil.

A first electrode layer is formed over the circumferential surface region of the tubular glass substrate (Step 106). The first electrode layer is molybdenum material/alloy in a specific embodiment. Other electrode materials such as transparent conductive oxide material or metal may also be used, depending on the applications.

The method further includes forming an absorber layer over the first electrode layer (Step 108) and forming a window buffer layer over the absorber layer (Step 110). In a specific embodiment, the absorber layer is a copper indium gallium diselenide CIGS material or a copper indium diselenide CIS material, while the window buffer layer is a cadmium sulfide or zinc oxide.

The tubular glass substrate, including the absorber layer and the window buffer layer formed on its circumferential surface region, are loaded into a chamber (Step 112), preferably with a substantially co-axial cylindrical heating rod inserted within the inner diameter and extending through the length of the tubular glass substrate. The cylindrical heating rod can be a solid resistive heater to provide radiation/conduction heat to the tubular glass substrate from inside out. In another embodiment, the cylindrical heating rod can be a spindle having a hollow interior with running hot fluid and an inflatable surface that can be made to intimately contact the inner surface of the tubular glass substrate to provide thermal energy uniformly from inside out.

The tubular glass substrate is introduced to a vacuum environment (Step 114) by pumping the chamber to a pressure below 0.1 Torr. Then a mixture of reactant species derived from a zinc bearing species and water species and a carrier gas are introduced into the chamber with controlled flow rate and monitored chamber pressure (Step 116). The zinc bearing species can be provided by diethylzinc gas, or by other types of zinc bearing chemical materials. The method introduces a diborane species using a selected flow rate into the mixture of reactant species in a specific embodiment. The diborane species acts as the dopant for achieving a desired electrical property of the film. Depending on the chamber configuration and loading mechanism of the tubular substrate, both the gaseous mixture of reactant species and the dopant species are distributed substantially uniformly throughout the circumferential outer surface region of the tubular glass substrate. In another embodiment, the tubular glass substrate can be loaded in such a way that it can be rotated to allow the whole circumferential surface region to be exposed uniformly to the distributed gaseous mixture of reactant species and dopant species.

In a specific embodiment, the method includes a process of transferring thermal energy from the cylindrical heating rod (Step 118) outward to the tubular glass substrate to maintain a predetermined temperature uniformly. The process can be started before, during, and after introducing the mixture of reactant species including zinc species, water species, diborane species, together with a carrier gas into the chamber. In an embodiment, the surface region is held at about a temperature ranging from about 130 degrees Celsius to about 190 degrees Celsius. In another embodiment, the substrate is maintained at a temperature greater than about 200 degrees Celsius. The heating rod can be heated through a resistive heating method using an adjustable DC current. In one embodiment, the heating rod has its two electric leads respectively passing through a sealed cap (covering the ends of the tubular glass substrate). In another embodiment, the heating rod is also a spindle which carries hot fluid and has an inflatable surface. Once inserted into the inner cavity of the tubular glass substrate, the inflatable surface of the spindle can be made solid intimate contact with the inner surface of the tubular glass substrate to provide efficient heat transfer. These processes also apply for loading a plurality of tubular glass substrates together in a substantially the same manner. Depending on application, the tubular glass substrate can be heated to a desired temperature for inducing chemical reaction on the exposed window buffer layer overlying the circumferential outer surface region on which the gaseous mixture of reactant species and dopant species is uniformly distributed throughout. In a specific embodiment, the chemical reaction induced thin film formation process is a process based on Metal-Organic Chemical Vapor Deposition (MOCVD) technique.

Furthermore, the preferred method herein includes a process for forming a zinc oxide film (Step 120) over the window layer (on the outer surface region of the tubular glass substrate). Step 120 includes the MOCVD deposition process used to form a zinc oxide film, as well as a thermal treatment process followed the deposition. In a specific embodiment, the zinc oxide film in its final format has a thickness from 0.75-3 μm, a haziness of 5% and greater, and an electrical resistivity of about 2.5 milliohm-cm and less. The zinc oxide film is a transparent conductive oxide material overlying the window buffer layer. The method performs other steps (Step 122) to complete the photovoltaic cell. The method ends with an END step (Step 124).

The sequence of steps above provides a method of forming a photovoltaic device according to an embodiment of the present invention, and includes a partially transparent conductive layer of zinc oxide film. The zinc oxide film preferably has an optical haziness of about 5% and greater. The “haze” is a macroscopic appearance of the surface arising from scattering of incident light by the surface microscopic morphology and the bulk grain structure of the zinc oxide film. “Haziness” can be considered as the ratio of the scattered component of transmitted light to the total amount of light transmitted by the partial transparent conductive oxide layer for the wavelengths of light to which the film itself is sensitive. The scattered component of incident light at least partially is only re-directed but still transmitted into the film (not reflected). The total transmission rate of light through the film can be greater than about 99 percent. The zinc oxide film is further characterized by its resistivity of about 2.5 milliohm-cm and less useful for fabricating a photovoltaic device. Of course, depending on the embodiment, steps may be added, eliminated, or performed in a different sequence without departing from the scope of the claims herein.

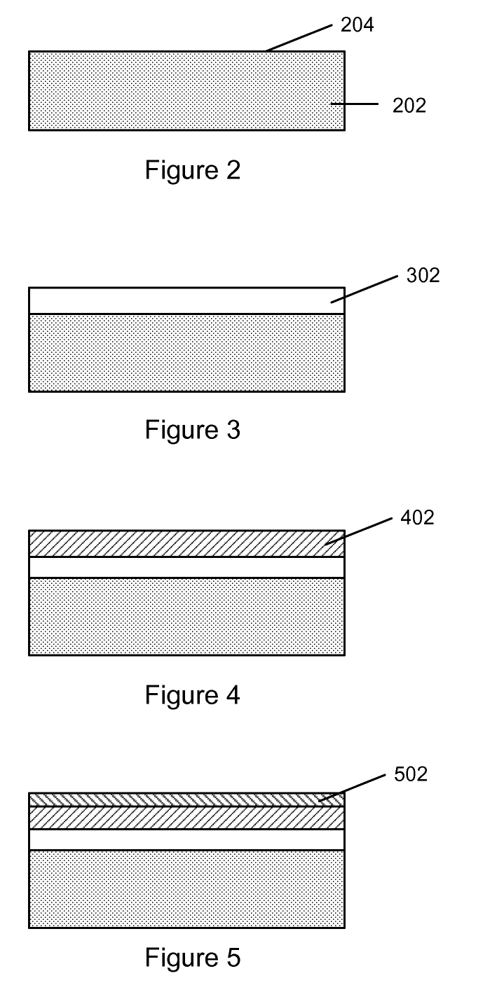

FIG. 2-6 are simplified diagrams illustrating a method of forming thin film photovoltaic devices on shaped substrates according to embodiments of the present invention. As shown in FIG. 2, a shaped substrate member 202 including a surface region 204 is provided. The figure shows an enlarged piece of the substrate member so that the actual shape is not visible, rather it is represented by a small plate.

The shaped substrate member can be a glass material such as soda lime glass, quartz, fused silica, or solar glass. The shaped substrate member is preferably a tubular shape characterized by an inner diameter and an outer diameter in this cross sectional view and a length (not shown). Of course other shapes can be used depending on the desired application. The shaped substrate member can include a barrier layer (not explicitly shown) deposited on the surface region. The barrier layer prevents sodium ions from the soda lime glass from diffusing into a photovoltaic thin film formed thereon. The barrier layer can be a dielectric material such as silicon oxide deposited using physical vapor deposition technique, e.g. a sputtering process, or a chemical vapor deposition process including plasma enhanced processes, and others. Other barrier materials may also be used. Suitable barrier materials include aluminum oxide, titanium nitride, silicon nitride, tantalum oxide, zirconium oxide depending on the embodiment.

As shown in FIG. 3, the method includes forming a first electrode layer 302 overlying the surface region of the shaped substrate member which may have a barrier layer formed thereon. The first electrode layer may be provided using a transparent conductor oxide (TCO) such as indium tin oxide (commonly called ITO), fluorine doped tin oxide, and the like. In certain embodiments, the first electrode layer is provided by a metal such as molybdenum or alloy. The molybdenum can be deposited using deposition techniques such as sputtering, plating, physical vapor deposition (including evaporation, sublimation), chemical vapor deposition (including plasma enhanced processes) following by a patterning process. Molybdenum provides advantage over other materials for a CIG or CIGS based thin film photovoltaic cells. In particular, molybdenum has low contact resistance and film stability over subsequent processing steps.

In one embodiment, molybdenum is formed by depositing a first molybdenum layer overlying the shaped substrate member. The first molybdenum layer has a first thickness and a tensile stress characteristics. A second molybdenum layer having a compression stress characteristics and a second thickness is formed over the first molybdenum layer. Then the two layers of molybdenum material can be further patterned as shown. Further details of deposition and patterning of the molybdenum material can be found in Provisional U.S. Patent Application No. 61/101,646 and Non-provisional U.S. patent application Ser. No. 12/567,698 filed Sep. 30, 2008 and U.S. Provision Application No. 61/101,650 filed Sep. 30, 2008, commonly assigned, and hereby incorporated by reference.

As shown in FIG. 4, an absorber layer 402 is formed over a surface region of the first electrode layer. The absorber layer can be a thin film semiconductor material, e.g. a p-type semiconductor material provided by a copper indium disulfide material, a copper indium gallium disulfide material, a copper indium diselenide material, or a copper indium gallium diselenide material, as well as combinations of these. Typically, the p-type characteristics are provided using dopants, such as boron or aluminum species. The absorber layer 402 may be deposited by techniques such as sputtering, plating, evaporation including a sulfurization or selenization step. Further details of the formation of the absorber material may be found in Provisional U.S. Patent Application No. 61/059,253 and Non-provisional application Ser. No. 12/475,858, titled “High Efficiency Photovoltaic Cell and Manufacturing Method,” commonly assigned, and hereby incorporated by references.

A window buffer layer 502 is deposited over a surface region of the absorber layer to form a photovoltaic film stack for forming a pn junction of a photovoltaic cell. In a specific embodiment, the window buffer layer uses a cadmium sulfide material for a photovoltaic cell using CIGS, CIS and related materials as absorber layer. The window buffer layer can be deposited using techniques such as sputtering, vacuum evaporation, chemical bath deposition, among others. The window buffer layer is a layer formed before a window layer is formed. In an embodiment, the window layer often uses a wide bandgap n-type semiconductor material for the p-type absorber layer. In a specific embodiment, the window layer has suitable optical characteristics and suitable electrical properties for a photovoltaic solar cell. For example, transparent conductive oxide such as zinc oxide material deposited by MOCVD technique can be used.

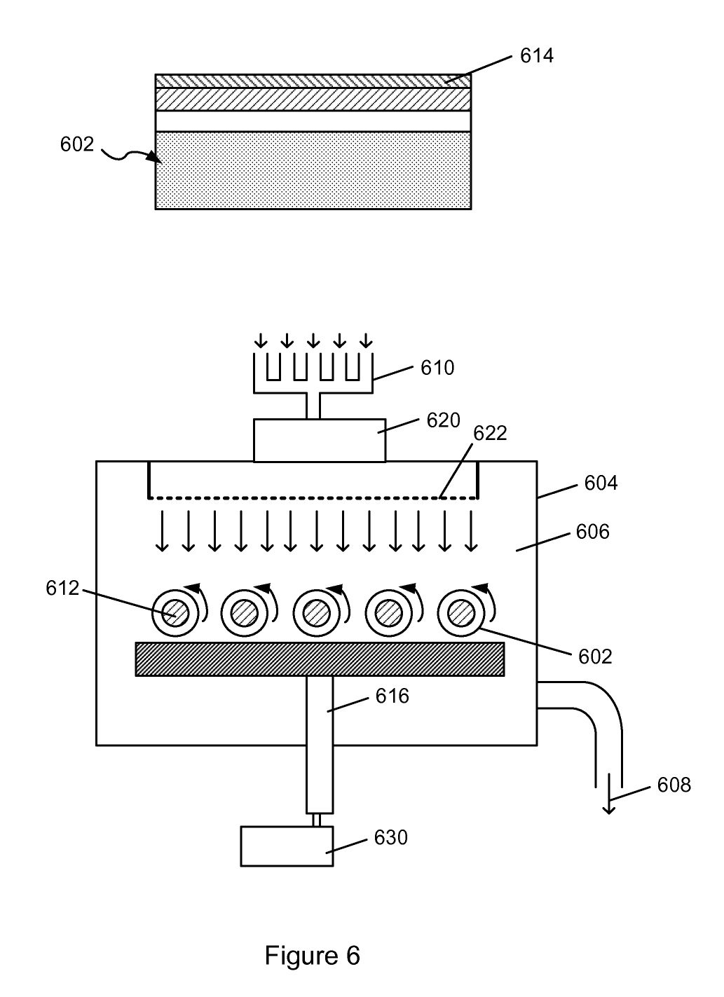

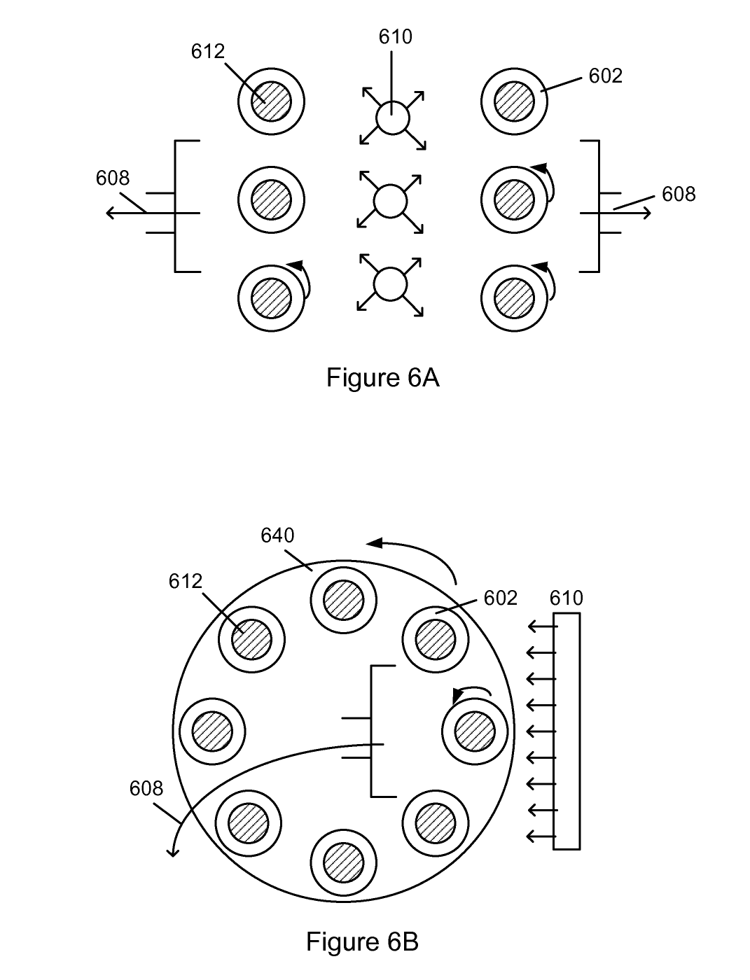

Referring to FIG. 6, the method includes providing one or more tubular glass substrates 602. The tubular glass substrate includes a circumferential outer surface region having an overlying first electrode layer. A thin film absorber layer overlies the first electrode layer and a window buffer layer overlies the thin film absorber layer. As shown, the one or more tubular glass substrates 602 are loaded into a chamber 604 in such a way (using a loading tool 616) that the tubular glass substrate 602 is co-centered with a heating rod 612 inserted within an inner diameter of the tubular glass substrate 602 extending from one end to another through its length. The heating rod 612 provides thermal energy to the circumferential outer surface region of the tubular glass substrate by resistive heating using DC current through direct conduction or radiation. The heating rod 612 can be also a spindle which carries hot fluid inside and has an inflatable surface to make intimate contact (once inserted into the tubular substrate) for provide efficient heat transfer. Merely as an example, using the co-centered heating rod provides a simple and effective process configuration for delivering thermal energy needed for maintaining the tubular glass substrate at a certain elevated reactive temperature during the formation of the hazy zinc oxide film on the tubular shaped substrate. Alternatively, the heating rod can act as mechanical spindle to couple with a motor shaft to drive the rotation of the tubular substrate 602 during thin film deposition. Other heating methods, like using microwave chamber configured specifically to provide a uniform reactive and annealing temperature for a particular shaped substrate member including cylindrical, tubular, spherical, or other non-planar shapes, can be used.

The chamber 604 includes an internal volume 606 which can be configured to allow multiple tubular glass substrates being loaded in substantially the same manner mentioned above. In a preferred embodiment, a co-centered heating rod is inserted to each of the plurality of tubular glass substrates 602. The chamber 604 also couples a pumping system 608 to provide a suitable vacuum level. As shown, the chamber 604 couples one or more gas lines 610 and various auxiliaries such as gas mixer 620 and shower head distributor 622 to introduce one or more gaseous precursor species for forming a transparent conductive oxide material 614 with a certain degree of haziness overlying the window layer in a specific embodiment. As shown in FIG. 6, in a specific embodiment, the one or more gaseous species are injected in a linear direction while the tubular substrates are rotated to allow uniform deposition.

Referring to FIG. 6A, a simplified sectional view of an alternative substrate/gas distributor configuration is illustrated according to an embodiment of the present invention. As shown, a plurality of gas lines 610 is interdigitatedly distributed with a plurality of tubular substrates 602 (each held and heated by a co-centered rod 612). Each gas line distributes the mixture of species in radial direction and each tubular substrate 602 can be rotated for achieving a desired dose during thin film deposition around the circumferential outer surface region of the substrates.

Referring to FIG. 6B, an alternative configuration is provided for the gas distribution. As shown, a group of tubular substrates are loaded onto a rotating stage 640 which has at least a section located near a plurality of gas lines 610 which inject gas towards the one or more tubular substrates nearby in a substantially one dimensional direction (left). Each of the tubular substrates 602 loaded on the stage 640 can have self-rotation with a proper rpm to allow its circumferential surface to be uniformly exposed to the injected gas. An exhaust 608 can be installed near the central portion of the stage and substantially prevents the one-dimensional flow of the gas from reaching rest tubular substrates other than a few near the gas lines.

In another specific embodiment, the gaseous precursor species include zinc bearing species, oxygen bearing species, dopant species, and at least one carrier gases. In an implementation, the chamber also couples to a power supply 630 connected to one or more heating devices 612 to provide a suitable reaction temperature for the deposition a thin film comprising the precursor and dopant materials as well as a proper annealing temperature for treating the thin film followed the deposition. In another implementation, the chamber couples to a running hot fluid source 630 through pipes connected to the heating devices 612 to supply thermal energy.

Referring again to FIG. 6, the chamber together with the tubular glass substrates is pumped down to a pressure ranging from about 0.1 torr to about 0.02 torr. A mixture of reactant or precursor species is introduced into the chamber using the gas lines. For the zinc oxide material, the mixture of reactant species can include a diethyl zinc material and an oxygen bearing species provided with a carrier gas. The oxygen bearing species can be water vapor in a specific embodiment. The diethyl zinc material may be provided as a semiconductor grade gas, or a catalyst grade gas depending on the embodiment. Preferably the water to diethylzinc ratio is controlled to be greater than about 1 to about 4. In another embodiment, the water to diethylzinc ratio is about 1, while the carrier gas can be an inert gases such as nitrogen, argon, helium, and the like. In certain embodiment, a boron bearing species derived from a diborane species may also be introduced at a selected flow rate together with the mixture of reactants as a dopant material for the thin film to be formed. Boron doping provides suitable electric conductivity in the hazy zinc oxide TCO material for CIGS/CIS based photovoltaic cell. Other boron bearing species such as boron halides (for example, boron trichloride, boron trifluoride, boron tribromide), or boron hydrohalides may also be used depending on the application. The diborane species is provided at a diborane-to-diethylzinc ratio of zero percent to about five percent. In a specific embodiment, the diborane-to-diethylzinc ratio is about one percent.

Depending on the embodiment, the chamber can be at a pressure of about 0.5 Torr to about 1 Torr during deposition of the precursor plus dopant material. In a specific embodiment, the substrate is maintained at a temperature ranging from about 130 degrees Celsius to about 190 degrees Celsius during the deposition. In an alternative embodiment, the substrate is maintained at a temperature of about 200 degrees Celsius and may be higher. In a preferred embodiment, the co-centered heating rod 612 provides uniform heating for the tubular shaped glass substrate throughout the whole circumferential outer surface region. The uniform substrate temperature as provided and the dopant species supplied with proper selected flow rate cause a formation of a zinc oxide film with desired surface morphology as well as proper bulk grain structure. Correspondingly both the surface morphology and the bulk grain structure contribute to suitable optical transmission as well as electrical conduction characteristics for the zinc oxide film. In a specific embodiment, depending on the level of boron bearing species and at a proper substrate temperature range, the zinc oxide film formed can have a bulk grain size ranging from about 3000 Angstroms to about 5000 Angstroms. The surface morphology of the substantially crystallized film is characterized by a plurality of microscopic triangular shaped facets or pyramids within its surface region. The microscopic roughened surface region comprises about a few percent of the total thickness (ranging from 0.75 to about 3 μm) of the zinc oxide film. Both the roughed surface morphology with the facet micro-structure and suitable bulk grain structure contribute a macroscopic hazy appearance by scattering or diffusing the incident light. Along each light path, the light scattering causes enhanced photon trapping and potentially enhanced light-to-electricity conversion efficiency. In a specific embodiment, a desired haziness is about 5% or greater, while the total optical transmission rate is of 80 percent or greater and preferably 90 percent and greater for incident light in a wavelength range ranging from about 800 nanometers to about 1200 nanometers. In another embodiment, the total transmission of incident light to through the zinc oxide film is near 99% or greater.

Additionally, the boron bearing species reduces a resistivity characteristic of the zinc oxide film formed. Depending on a doping level of the boron bearing species, in a specific embodiment, the zinc oxide film formed above can have a resistivity of about 2.5 milliohm-cm and less, which is a desired electric characteristic for the CIGS/CIS based photovoltaic cell. Further, both the roughed surface morphology and the bulk grain size ranging from about 3000 Angstroms to about 5000 Angstroms provide a desired structure leading to suitable sheet resistance useful for fabricating photovoltaic devices.

While the present invention has been described using specific embodiments, it should be understood that various changes, modifications, and variations to the method utilized in the present invention may be effected without departing from the spirit and scope of the present invention as defined in the appended claims. For example, the tubular shaped substrate is illustrated. Other substrates in regular or irregular shape, planar or non-planar shape, rigid or flexible in mechanical characteristic, transparent or non-transparent (to visible light) in optical characteristic, and the like can be applied by the present invention. In an example, zinc oxide material is illustrated using boron as a dopant species. Other dopants such as hydrogen, aluminum, indium, gallium, and the likes may also be used. Additionally, although the above has been generally described in terms of a specific layered structure for CIS and/or CIGS thin film photovoltaic cells, other specific CIS and/or CIGS thin film configurations can also be used, such as those noted in U.S. Pat. No. 4,612,411 and U.S. Pat. No. 4,611,091, which are hereby incorporated by reference herein, without departing from the invention described by the claims herein. Additionally, embodiments according to the present invention can be applied to other thin film configurations such as those provided by a metal oxide material, a metal sulfide material or a metal selenide material.

What is claimed is:

1. A method for fabricating a shaped thin film photovoltaic device, the method comprising:
providing a length of tubular glass substrate having an inner diameter, an outer diameter, a circumferential outer surface region covered by an absorber layer and a window buffer layer overlying the absorber layer;
subjecting the tubular glass substrate in a vacuum environment of between about 0.1 Torr to about 0.02 Torr;
introducing a mixture of reactant species derived from diethylzinc species, water species, and a carrier gas to the vacuum environment;
introducing a diborane species into the mixture of reactant species;
heating tubular glass substrate; and
forming a zinc oxide film overlying the window buffer layer, the zinc oxide film having a thickness of 0.75-3 μm, a haziness of at least 5%, and an electrical resistivity of less than about 2.5 milliohm-cm.

2. The method of claim 1 wherein the zinc oxide film further is characterized by an average grain size of about 3000 Angstroms to about 5000 Angstroms.

3. The method of claim 1 wherein the diethylzinc species comprises dielethyl vapor.

4. The method of claim 1 wherein the water species comprises water vapor.

5. The method of claim 1 wherein the carrier gas comprises an inert gas.

6. The method of claim 1 wherein the reactant species has a water-to-diethylzinc ratio between about 1 and about 4.

7. The method of claim 1 wherein the diborane to diethylzinc ratio is from about zero to about five percent.

8. The method of claim 1 wherein introducing the diborane species using a selected flow rate comprises controlling diborane to diethylzinc ratio to about one percent.

9. The method of claim 1 wherein the tubular glass substrate is heated to a temperature range from about 130 degrees Celsius to about 190 degrees Celsius.

10. The method of claim 1 wherein the tubular glass substrate is maintained at a temperature greater than about 200 degrees Celsius.

11. The method of claim 1 wherein transferring an amount of thermal energy comprises resistive heating of the heating rod.

12. The method of claim 1 wherein the heating rod comprises a spindle carrying running hot fluid and an inflatable surface configured to, after being inserted, make intimate contact with an inner surface of the tubular glass substrate.

13. The method of claim 1 wherein the zinc oxide film with the haziness of about 5% and greater has a total optical transmission rate of 90 percent and greater.

14. The method of claim 1 wherein the zinc oxide film with the haziness of about 5% and greater has a transmission rate of 80 percent and greater for electromagnetic radiation having a wavelength of about 800 nanometers to about 1200 nanometers.

15. The method of claim 1 wherein introducing a mixture of reactant species increases a pressure of the chamber to about 0.5 to 1 Torr.

16. The method of claim 1 wherein the absorber layer comprises a CIGS material or a CIG material.

17. The method of claim 1 wherein the window buffer layer comprises a cadmium sulfide material.

18. A method for forming a thin film photovoltaic device, the method comprising:
providing a shaped substrate member including a surface region;
forming a first electrode layer overlying the surface region;
forming an absorber material comprising a copper species, an indium species, and a selenide species overlying the first electrode layer;
forming a window buffer layer comprising a cadmium selenide species overlying the absorber material; and
forming a zinc oxide layer of about 0.75 to 3 microns in thickness overlying the window buffer layer using one or more precursor gases including a zinc species and an oxygen species and an inert carrier gas;
wherein the shaped substrate member is maintained at a temperature of greater than about 130 degrees Celsius substantially uniformly throughout the surface region during a chemical reaction of the one or more precursor gases thereon and extended annealing of the zinc oxide layer, thereby leading to a hazy surface optical characteristics and a bulk grain size of about 3000 Angstroms to about 5000 Angstroms within the zinc oxide layer.

19. The method of claim 18 wherein the hazy surface optical characteristics comprises a ratio about 5% and greater of a scattered component of transmitted light to the total amount of light transmitted through the zinc oxide layer.

20. The method of claim 18 wherein the chemical reaction of the one or more precursor gases occurs with at least a dopant gas comprising boron species being added at a preselected flow rate.

21. The method of claim 20 wherein the added boron species causes the zinc oxide layer to have a sheet resistivity of about 2.5 milliohm-cm and less.

22. The method of claim 20 wherein the chemical reaction is a deposition process based on Metal-Organic Chemical Vapor Deposition technique.

23. A structure for thin-film photovoltaic device, the structure comprising:
a shaped substrate member including a surface region;
a first electrode film overlying the surface region;
an absorber material comprising a copper species, an indium species, and a selenide species overlying the first electrode film;
a window buffer layer comprising a cadmium selenide species overlying the absorber material; and
a zinc oxide film of about 0.75 to 3 microns in thickness overlying the window buffer layer, the zinc oxide film being characterized by a thickness from 0.75-3 μm, a haziness of 5% and greater, and an electrical resistivity of about 2.5 milliohm-cm and less;
wherein the zinc oxide film is formed via extended annealing of the shaped substrate member at a temperature greater than about 130 degrees Celsius substantially uniformly throughout the surface region within an ambient of precursor gases including a zinc species, an oxygen species, and an inert carrier gas.

24. The structure of claim 23 wherein the zinc oxide film further is characterized by an average grain size of about 3000 Angstroms to about 5000 Angstroms.

25. The structure of claim 23 wherein the shaped substrate member comprises a glass.

26. The structure of claim 23 wherein the precursor gases comprise diethylzinc species, water species, and an inert gas.

27. The structure of claim 23 wherein the zinc oxide film characterized by the haziness of about 5% and greater has a total optical transmission rate of at least 90 percent.
